(19) United States
(12) Patent Application Publication
(10) Pub. No.: US 2026/0215033 A1
(43) Pub. Date: Jul. 23, 2026

(54) METHOD FOR PRODUCING AN OPTOELECTRONIC COMPONENT, AND OPTOELECTRONIC COMPONENT

(71) Applicant: ams-OSRAM International GmbH, Regensburg (DE)

(72) Inventors: Hermann Nuss, Regensburg (DE); Peter Blum, Regensburg (DE)

(21) Appl. No.: 19/142,918

(22) PCT Filed: May 7, 2024
(86) PCT No.: PCT/EP2024/062631

§ 371 Date: Jun. 24, 2025

(30) Foreign Application Priority Data
May 9, 2023 (DE) 10 2023 112 181.2

(51) Int. Cl. H10H 20/01; H10H 20/851; H10H 20/853; H10H 20/857

(52) U.S. Cl. CPC H10H 20/0362; H10H 20/0361; H10H 20/851; H10H 20/853; H10H 20/857

(57) ABSTRACT

In an embodiment a method includes providing a first molded body having an embedded leadframe, wherein sections of a top side of the leadframe are exposed on a top side of the first molded body and sections of an underside of the leadframe are exposed on an underside of the first molded body, arranging an optoelectronic element including an optoelectronic semiconductor chip on the top side of the first molded body such that a top side of the optoelectronic element faces away from the top side of the first molded body and forming a second molded body on the top side of the first molded body, wherein the optoelectronic element is embedded in the second molded body, and wherein the top side of the optoelectronic element is at least not entirely covered by the second molded body.

### CROSS-REFERENCE TO RELATED APPLICATIONS

This patent application is a national phase filing under section 371 of PCT/EP2024/062631, filed May 7, 2024, which claims the priority of German patent application no. 10 2023 112 181.2, filed May 9, 2023, each of which is incorporated herein by reference in its entirety.

### TECHNICAL FIELD

The present invention relates to a method for producing an optoelectronic component and to an optoelectronic component.

### BACKGROUND

In the production of optoelectronic components, it is known to embed leadframes in molded bodies.

### SUMMARY

Embodiments provide a method for producing an optoelectronic component. Further embodiments provide an optoelectronic component.

A method for producing an optoelectronic component comprises steps for providing a first molded body comprising an embedded leadframe, wherein sections of a top side of the leadframe are exposed on a top side of the first molded body and sections of an underside of the leadframe are exposed on an underside of the first molded body, for arranging an optoelectronic element comprising an optoelectronic semiconductor chip on the top side of the first molded body such that a top side of the optoelectronic element faces away from the top side of the first molded body, and for forming a second molded body on the top side of the first molded body, wherein the optoelectronic element is embedded in the second molded body, wherein the top side of the optoelectronic element is at least not entirely covered by the second molded body.

In this method, the leadframe has already been embedded in the first molded body before the optoelectronic element is arranged on the leadframe and embedded in the second molded body. This affords the advantage that the arrangement and electrical contacting of the optoelectronic element are simplified and, under certain circumstances, may take place without the use of a rear-side adhesive film. This may be accompanied by reduced contamination by outgassing from the adhesive film. A further advantage of the method is that the configuration of the second molded body may take place independently of the configuration of the first molded body. This makes it possible to carry out different method variants with different configurations of the second molded body, but in so doing to use uniformly configured first molded bodies in each case. A further advantage of the method may be that the first molded body may be formed from a hard material, thus resulting in good sawing properties of the optoelectronic component obtainable by the method.

In one embodiment of the method, providing the first molded body comprises steps for providing a leadframe and for forming the first molded body. In this case, the leadframe is embedded in the first molded body. The sections of the top side of the leadframe and the sections of the underside of the leadframe are not covered by the first molded body. A particular advantage of this method is that these steps for providing the first molded body may take place independently of the other method steps for producing the optoelectronic component. In this regard, it is possible, for example, for the steps for providing the first molded body to be carried out by a supplier.

In one embodiment of the method, the first molded body is formed from a first molding material, for example from an epoxy. One advantage of the method is that the material of the first molded body may be chosen independently of the material of the second molded body. This may make it possible, for example, to form the first molded body from a particularly hard first molding material, and this may result in expedient mechanical properties of the optoelectronic component obtainable by the method.

In one embodiment of the method, the first molding material comprises a black color. This may advantageously contribute to minimizing undesirable light reflections at the first molded body.

In one embodiment of the method, the first molded body is formed by way of a molding method, for example by film assisted transfer molding. This advantageously enables simple and cost-effective production of the first molded body. In particular, this makes it possible to embed the leadframe in the first molded body in such a way that sections of the top side of the leadframe are exposed on the top side of the first molded body and sections of the underside of the leadframe are exposed on the underside of the first molded body.

In one embodiment of the method, the top side of the first molded body is planar. In this case, the sections of the top side of the leadframe which are exposed on the top side of the first molded body terminate flush with the top side of the first molded body. This advantageously results in a particularly simple and compact configuration of the first molded body which makes it possible to arrange and electrically contact the optoelectronic element on the top side of the first molded body in a simple manner. This configuration of the first molded body advantageously additionally facilitates the formation of the second molded body on the top side of the first molded body.

In one embodiment of the method, the second molded body is formed from a second molding material, for example from a silicone or an epoxy. Advantageously, the second molding material may be chosen independently of the material of the first molded body.

In one embodiment of the method, the second molding material comprises a white color. This affords the advantage that light emitted by the optoelectronic element of the optoelectronic component obtainable by the method may be reflected at the second molded body.

In one embodiment of the method, the second molded body is formed by way of a molding method, for example by a film assisted molding method. This advantageously enables simple and cost-effective production of the second molded body and allows the second molded body to be formed such that the top side of the optoelectronic element is at least not entirely covered by the second molded body.

In one embodiment of the method, the top side of the optoelectronic element terminates flush with a top side of the second molded body. This advantageously results in a particularly simple and robust configuration of the optoelectronic component.

In one embodiment of the method, the top side of the second molded body is planar. As a result, the optoelectronic component obtainable by the method advantageously comprises a particularly compact and simple outer shape. However, it is also possible for the top side of the second molded body to be formed in a manner other than planar.

In one embodiment of the method, the optoelectronic element is formed to emit light at its top side. By way of example, the optoelectronic element may be formed to emit visible light comprising a white light color. The optoelectronic component obtainable by the method may then be used for illumination purposes, for example.

In one embodiment of the method, the optoelectronic semiconductor chip is formed as a flip-chip. This makes it possible to electrically conductively connect the optoelectronic semiconductor chip to the leadframe without the use of bond wires.

In one embodiment of the method, a wavelength-converting element constituting the top side of the optoelectronic element is arranged on a top side of the optoelectronic semiconductor chip. The wavelength-converting element may be provided to convert light emitted by the optoelectronic semiconductor chip at least partly into light of a different wavelength.

In one embodiment of the method, in addition to the optoelectronic semiconductor chip a further semiconductor chip is arranged on the top side of the first molded body, for example a protective diode chip. In this case, the further semiconductor chip may for example be entirely embedded in the second molded body. This advantageously makes it possible for the optoelectronic component obtainable by the method to be equipped with additional functionality, for example with protection against damage to the optoelectronic semiconductor chip.

An optoelectronic component comprises a first molded body comprising an embedded leadframe. Sections of a top side of the leadframe and sections of an underside of the leadframe are not covered by the first molded body. The optoelectronic component additionally comprises an optoelectronic comprising an optoelectronic semiconductor chip, said optoelectronic element being arranged on a top side of the first molded body such that a top side of the optoelectronic element faces away from the top side of the first molded body. The optoelectronic component further comprises a second molded body arranged on the top side of the first molded body. The optoelectronic element is embedded in the second molded body. The top side of the optoelectronic element is at least not entirely covered by the second molded body.

In the case of this optoelectronic component, the first molded body may be produced and configured independently of the second molded body. This advantageously allows the properties of the first molded body to be optimized independently of the properties of the second molded body, such that the optoelectronic component may comprise particularly expedient mechanical properties, for example. The subdivision into the first molded body and the second molded body may also make it possible to produce different optoelectronic components comprising differently configured second molded bodies but uniformly configured first molded bodies, which advantageously enables particularly cost-effective production of these optoelectronic components.

### BRIEF DESCRIPTION OF THE DRAWINGS

The above-described properties, features and advantages of this invention and the way in which they are achieved will become clearer and more clearly understood in association with the following description of the exemplary embodiments which are explained in greater detail in association with the drawings, in which, in each case in a schematic illustration:

FIG. 1 shows a leadframe;

FIG. 2 shows a first molded body, in which the leadframe has been embedded;

FIG. 3 shows a component part section of the first molded body comprising an optoelectronic element arranged on the top side;

FIG. 4 shows an optoelectronic component comprising the first molded body, the optoelectronic element and a second molded body; and

FIG. 5 shows a component part section of the first molded body comprising a differently configured optoelectronic element.

### DETAILED DESCRIPTION OF ILLUSTRATIVE EMBODIMENTS

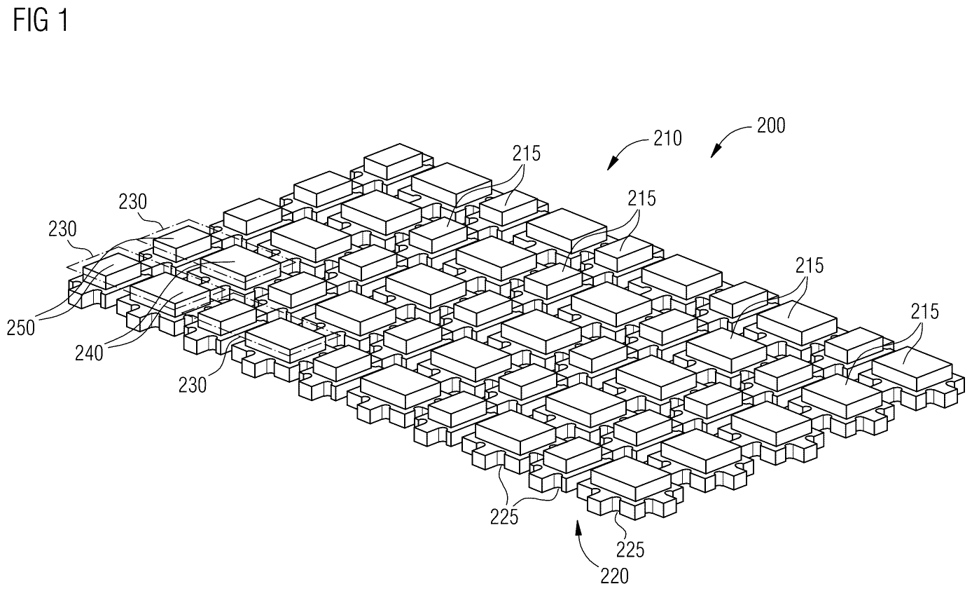

FIG. 1 shows a schematic perspective illustration of a leadframe 200. The term “Leadframe” may also be used in German for the leadframe 200. The leadframe 200 comprises an extensive, planar and flat basic shape comprising a top side 210 and an underside 220 opposite the top side 210. The leadframe 200 comprises an electrically conductive material, for example a metal such as copper. The leadframe 200 may be produced from a metal sheet by etching, for example.

The leadframe 200 comprises a plurality of identically formed component part sections 230 which are integrally continuously connected to one another in a regular matrix arrangement. In this case, the individual component part sections 230 are connected to one another via webs which may be severed in a later method step in order to separate the component part sections 230 from one another. The leadframe 200 may comprise a larger number of component part sections 230 than is illustrated in FIG. 1.

In the example shown in FIG. 1, each component part section 230 comprises in each case a first part 240 and a second part 250. After the respective component part section 230 has been singulated, the first part 240 and the second part 250 of each component part section 230 are separated from one another and electrically insulated relative to one another. In other variants of the leadframe 200, the component part sections 230 may comprise further parts in addition to the first part 240 and the second part 250.

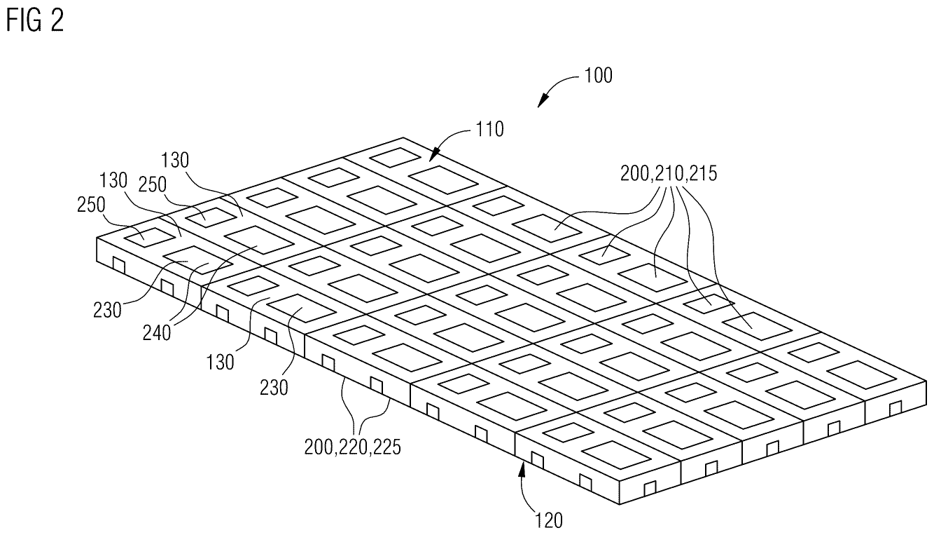

FIG. 2 shows a schematic perspective illustration of a first molded body 100. The first molded body 100 may also be referred to as a mold body or as a panel. The first molded body 100 has been formed from an electrically insulating first molding material (mold material) by way of a molding method (mold method). In this case, the leadframe 200 has been embedded in the first molded body 100. The first molded body 100 comprises a substantially flat and planar shape comprising a top side 110 and an underside 120 opposite the top side 110.

The leadframe 200 has been embedded in the first molded body 100 in such a way that sections 215 of the top side 210 of the leadframe 200 are exposed on the top side 110 of the first molded body 100 and sections 225 of the underside 220 of the leadframe 200 are exposed on the underside 120 of the first molded body 100. The exposed sections 215 of the top side 210 of the leadframe 200, in the case of each component part section 230, comprise a section of the first part 240 and a section of the second part 250. Likewise, the exposed sections 225 of the underside 220 of the leadframe 200, in the case of each component part section 230, comprise a section of the first part 240 and a section of the second part 250.

The first molded body 100 may have been formed by film assisted transfer molding, for example. In this case, during the molding method, the exposed sections 215 of the top side 210 of the leadframe 200 and the exposed sections 225 of the underside 220 of the leadframe 200 have been covered by films and thereby protected against being covered by the material of the first molded body 100.

The first molding material may comprise an epoxy or a silicone, for example. The first molding material may comprise a black color, for example. However, a white color or a different color is also possible.

The top side 110 of the first molded body 100 is planar in the example illustrated. The sections 215 of the top side 210 of the leadframe 200 which are exposed on the top side 110 of the first molded body 100 terminate flush with the top side 110 of the first molded body 100.

Accordingly, in the example illustrated, the underside 120 of the first molded body 100 is also planar. The exposed sections 225 of the underside 220 of the leadframe 200 terminate flush with the underside 120 of the first molded body 100.

The first molded body 100 comprises a plurality of component part sections 130 which are arranged in a matrix-shaped fashion and are integrally interlinked. The leadframe 200 is embedded in the first molded body 100 in such a way that each component part section 130 of the first molded body 100 comprises a component part section 230 of the leadframe 200.

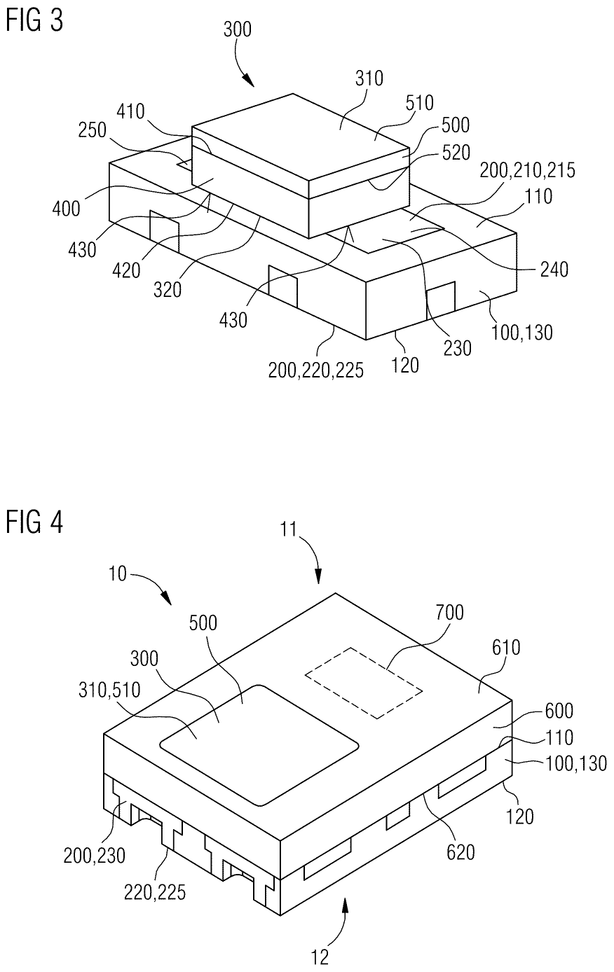

FIG. 3 shows a schematic perspective illustration of a component part section 130 of the first molded body 100 in a processing state temporally succeeding the illustration in FIG. 2. In FIG. 3, the component part section 130 is illustrated in a manner separated from the other component part sections 130 of the first molded body 100, for the sake of clarity. In actual fact, the component part sections 130 of the first molded body 100 are still connected to one another, however, in the processing state shown in FIG. 3.

An optoelectronic element 300 has been arranged on the top side 110 of the component part section 130 of the first molded body 100. The optoelectronic element 300 comprises a top side 310 and an underside 320 opposite the top side 310. The optoelectronic element 300 has been arranged on the top side 110 of the first molded body 100 such that the underside 320 of the optoelectronic element 300 faces the top side 110 of the first molded body 100 and the top side 310 of the optoelectronic element 300 faces away from the top side 110 of the first molded body 100.

The optoelectronic element 300 is formed to emit electromagnetic radiation (light) at its top side 310, for example visible light. For this purpose, the optoelectronic element 300 comprises an optoelectronic semiconductor chip 400 comprising a top side 410 and an underside 420 opposite the top side 410. The optoelectronic semiconductor chip 400 may be a light-emitting diode chip (LED chip), for example, and is formed to emit electromagnetic radiation at its top side 410.

In the example illustrated, the optoelectronic element 300 additionally comprises a wavelength-converting element 500 arranged on the top side 410 of the optoelectronic semiconductor chip 400. In this case, an underside 520 of the wavelength-converting element 500 faces the top side 410 of the optoelectronic semiconductor chip 400. A top side 510 of the wavelength-converting element 500, opposite the underside 520, constitutes the top side 310 of the optoelectronic element 300. The wavelength-converting element 500 is formed to convert light emitted by the optoelectronic semiconductor chip 400 at least partly into light of a different wavelength. By way of example, the optoelectronic semiconductor chip 400 may be formed to emit light comprising a wavelength from the blue spectral range. The wavelength-converting element 500 may be formed to convert this light partly into light comprising a wavelength from the yellow spectral range. A mixture of unconverted and converted light that is emitted at the top side 310 of the optoelectronic element 300 may then comprise a white light color.

If a conversion of the light generated by the optoelectronic semiconductor chip 400 is not required, the wavelength-converting element 500 may be omitted. In this case, the top side 310 of the optoelectronic element 300 is constituted by the top side 410 of the optoelectronic semiconductor chip 400.

The underside 420 of the optoelectronic semiconductor chip 400 constitutes the underside 320 of the optoelectronic element 300. In the example illustrated, a plurality of electrical contact pads 430 of the optoelectronic semiconductor chip 400 are arranged on the underside 420 of the optoelectronic semiconductor chip 400, and electrical voltage and electrical current may be applied to the optoelectronic semiconductor chip 400 via said contact pads. In this case, the optoelectronic semiconductor chip 400 is formed as a flip-chip. The electrical contact pads 430 are electrically conductively connected to the sections 215—exposed on the top side 110 of the first molded body 100—of the first part 240 and of the second part 250 of the component part section 230 of the leadframe 200 that is embedded in the component part section 130 of the first molded body 100. This makes it possible to supply the optoelectronic semiconductor chip 400 of the optoelectronic element 300 with electrical voltage and with electrical current via the first part 240 and the second part 250. The electrically conductive connections between the electrical contact pads 430 of the optoelectronic semiconductor chip 400 and the exposed sections 215 of the top side 210 of the first part 240 and of the second part 250 of the leadframe 200 may be produced by solder connections or electrically conductive adhesive connections, for example.

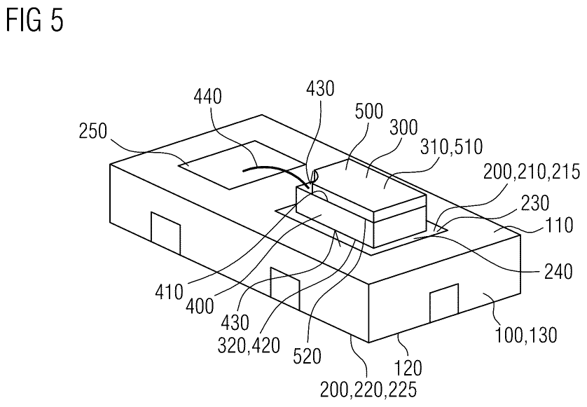

FIG. 4 shows a schematic perspective illustration of an optoelectronic component 10. The optoelectronic component 10 has been produced by further processing steps from the arrangement shown in FIG. 3.

Proceeding from the processing state shown in FIG. 3, firstly a second molded body (mold body) 600 has been formed on the top side 110 of the first molded body 100. In this case, the optoelectronic element 300 has been embedded in the second molded body 600 such that the top side 310 of the optoelectronic element 300 has been at least not entirely covered by the second molded body 600. Consequently, the top side 310 of the optoelectronic element 300 is at least partly exposed on a top side 610 of the second molded body 600 in the case of the optoelectronic component 10. The top side 610 of the second molded body 600 and the exposed top side 310 of the optoelectronic element 300 jointly constitute a top side 11 of the optoelectronic component 10.

The second molded body 600 comprises an underside 620 opposite the top side 610, said underside adjoining the top side 110 of the first molded body 100.

The second molded body 600 may have been formed for example by a molding method (mold method), for example by a film assisted molding method. In this case, during the process of forming the second molded body 600, the top side 310 of the optoelectronic element 300 has been covered by a film and thereby protected against being covered by the material of the second molded body 600.

The second molded body 600 has been formed from a second molding material (mold material), which may differ from or be identical to the first molding material of the first molded body 100. The second molding material of the second molded body 600 may comprise a silicone or an epoxy, for example. The second molding material may comprise a white color, for example. However, other colors, for example a black color, are likewise possible.

It is expedient if the top side 310 of the optoelectronic element 300 terminates flush with the top side 610 of the second molded body 600. In this case, the top side 610 of the second molded body 600 may be planar. However, it is also possible for the top side 610 of the second molded body 600 to be formed with a non-planar shape.

The underside 120 of the first molded body 100 constitutes an underside 12 of the optoelectronic component 10, opposite the top side 11. The optoelectronic component 10 may be electrically contacted via the sections 225 of the leadframe 200 that are exposed on the underside 120 of the first molded body 100. In this case, the optoelectronic component 10 may be suitable for example for surface mounting (SMT mounting), for example for mounting by reflow soldering.

After the formation of the second molded body 600, the optoelectronic component 10 has been singulated. In this case, the component part section 230 of the leadframe 200 that is embedded in the component part section 130 of the first molded body 100 has been separated from the other parts of the leadframe 200. Accordingly, the component part section 130 of the first molded body 100 has also been separated from the other parts of the first molded body 100. That part of the second molded body 600 which is associated with the optoelectronic component 10 has accordingly been separated from the other parts of the second molded body 600. The optoelectronic component 10 may have been singulated by a sawing process, for example.

In one variant of the optoelectronic component 10, the latter may comprise a further semiconductor chip 700 in addition to the optoelectronic semiconductor chip 400 of the optoelectronic element 300. Said further semiconductor chip is merely indicated in the schematic illustration in FIG. 4. The further semiconductor chip 700 may be a protective diode chip, for example, which may be provided for example for protecting the optoelectronic semiconductor chip 400 of the optoelectronic 300 against damage owing to an excessively high electrical voltage. In the processing state shown in FIG. 3, the further semiconductor chip 700 may be arranged alongside the optoelectronic element 300 on the top side 110 of the first molded body 100 and may be electrically conductively connected to the first part 240 and the second part 250 of the component part section 230 of the leadframe 200. Afterward, the further semiconductor chip 700 is embedded in the second molded body 600 during the process of forming the second molded body 600. In this case, the embedding may take place to such a complete degree that the further semiconductor chip 700 is not exposed on the top side 610 of the second molded body 600.

FIG. 5 shows a schematic perspective illustration of a processing state corresponding to the illustration in FIG. 3 during the production of a further variant of the optoelectronic component 10.

In the case of the variant shown in FIG. 5, an electrical contact pad 430 of the optoelectronic semiconductor chip 400 of the optoelectronic component 300 is arranged on the top side 410 of the optoelectronic semiconductor chip 400. A further electrical contact pad 430 is arranged on the underside 420 of the optoelectronic semiconductor chip 400. The optoelectronic element 300 has been arranged on the top side 110 of the first molded body 100 such that the electrical contact pad 430 arranged on the underside 420 of the optoelectronic semiconductor chip 400 is electrically conductively connected to the first part 240 of the component part section 230 of the leadframe 200. The electrical contact pad 430 arranged on the top side 410 of the optoelectronic semiconductor chip 400 has been electrically conductively connected to the second part 250 of the component part section 230 of the leadframe 200 by way of a bond wire 440. For this purpose, in the example illustrated, the wavelength-converting element 500 comprises a cutout that exposes the electrical contact pad 430 situated on the top side 410 of the optoelectronic semiconductor chip 400.

In the case of the variant shown in FIG. 5, too, the further processing takes place as described above with reference to FIGS. 3 and 4. In this case, the bond wire 440 is embedded jointly with the optoelectronic element 300 in the second molded body 600. As a result, the bond wire 440 is subsequently protected against damage owing to external influences. In the case of this variant, too, alongside the optoelectronic element 300, one or more further semiconductor chips 700 may be provided and embedded in the second molded body 600.

In further variants of the production method described, more than one optoelectronic element 300 is provided per optoelectronic component 10. In this case, optionally besides the first part 240 and the second part 250 the component part sections 230 of the leadframe 200 may each comprise even further parts that are electrically isolated from one another after the singulation of the respective component part section 230. The optoelectronic elements 300 of an optoelectronic component 10 may be arranged in electrical parallel or series circuits, for example. Combinations of series and parallel circuits are also possible. The optoelectronic elements 300 of an optoelectronic component 10 may be formed identically or differently.

The invention has been illustrated and described in greater detail on the basis of the preferred exemplary embodiments. Nevertheless, the invention is not restricted to the examples disclosed. Other variations may be derived by a person skilled in the art.

1.-16. (canceled)

17. A method for producing an optoelectronic component, the method comprising:
providing a first molded body comprising an embedded leadframe, wherein sections of a top side of the leadframe are exposed on a top side of the first molded body and sections of an underside of the leadframe are exposed on an underside of the first molded body;
arranging an optoelectronic element comprising an optoelectronic semiconductor chip on the top side of the first molded body such that a top side of the optoelectronic element faces away from the top side of the first molded body; and
forming a second molded body on the top side of the first molded body,
wherein the optoelectronic element is embedded in the second molded body, and
wherein the top side of the optoelectronic element is at least not entirely covered by the second molded body.

18. The method according to claim 17, wherein providing the first molded body comprises:
providing the leadframe; and
forming the first molded body,
wherein the leadframe is embedded in the first molded body, and
wherein the sections of the top side of the leadframe and the sections of the underside of the leadframe are not covered by the first molded body.

19. The method according to claim 18, wherein the first molded body is formed from a first molding material.

20. The method according to claim 19, wherein the first molding material comprises a black color.

21. The method according to claim 18, wherein the first molded body is formed by a film assisted transfer molding.

22. The method according to claim 17,
wherein the top side of the first molded body is planar,
wherein the sections of the top side of the leadframe, which are exposed on the top side of the first molded body. terminate flush with the top side of the first molded body.

23. The method according to claim 17, wherein the second molded body is formed from a second molding material.

24. The method according to claim 23, wherein the second molding material comprises a white color.

25. The method according to claim 17, wherein the second molded body is formed by a film assisted molding method.

26. The method according to claim 17, wherein the top side of the optoelectronic element terminates flush with a top side of the second molded body.

27. The method according to claim 26, wherein the top side of the second molded body is planar.

28. The method according to claim 17, wherein the optoelectronic element is configured to emit light at its top side.

29. The method according to claim 17, wherein the optoelectronic semiconductor chip is a flip-chip.

30. The method according to claim 17, wherein a wavelength-converting element constituting the top side of the optoelectronic element is arranged on a top side of the optoelectronic semiconductor chip.

31. The method according to claim 17, wherein, in addition to the optoelectronic semiconductor chip, a further semiconductor chip is arranged on the top side of the first molded body.

32. An optoelectronic component comprising:
a first molded body comprising an embedded leadframe, wherein sections of a top side of the leadframe and sections of an underside of the leadframe are not covered by the first molded body;
an optoelectronic element comprising an optoelectronic semiconductor chip, wherein the optoelectronic element is arranged on a top side of the first molded body such that a top side of the optoelectronic element faces away from the top side of the first molded body; and
a second molded body arranged on the top side of the first molded body,
wherein the optoelectronic element is embedded in the second molded body,
wherein the top side of the optoelectronic element is at least not entirely covered by the second molded body.
